(19) United States
(12) Patent Application Publication
(10) Pub. No.: US 2026/0012186 A1
(43) Pub. Date: Jan. 8, 2026

(54) HIGH BANDWIDTH LOW LATENCY DIE-TO-DIE CIRCUIT DESIGN

(71) Applicant: Taiwan Semiconductor Manufacturing Company, Ltd., Hsinchu (TW)

(72) Inventors: Tze-Chiang Huang, Hsinchu City (TW); Shrey Jayesh Bajaj, Hsinchu City (TW); Yun-Chia Chen, Hsinchu City (TW); Prashant Singh, Hsinchu City (TW); King-Ho Tam, Hsinchu City (TW); Chen-Jih Lui, Hsinchu City (TW)

(73) Assignee: Taiwan Semiconductor Manufacturing Company, Ltd., Hsinchu (TW)

(21) Appl. No.: 18/763,036

(22) Filed: Jul. 3, 2024

(51) Int. Cl. H03L 7/081; H03L 7/07; H04L 7/00

(52) U.S. Cl. CPC H03L 7/0814; H03L 7/07; H04L 7/0037

(57) ABSTRACT

A semiconductor device is provided. The semiconductor device includes a first die having a transmission circuit and a first phase-locked loop (PLL) circuit configured to generate a first global clock signal. The semiconductor device includes a second die having a receiver circuit, a phase aligned element, and a second PLL circuit. The phase aligned element is configured to generate a reference clock signal using the first global clock signal and feedback from the second PLL circuit. The second PLL circuit configured to generate a second global clock signal based on the reference clock signal. The phases of the first global clock signal and the second global clock signal are aligned to facilitate data transfer from the transmission circuit to the receiver circuit.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size (e.g., shrinking the semiconductor process node towards the sub-20 nm node), which allows more components to be integrated into a given area. As the demand for miniaturization, higher speed, and greater bandwidth, as well as lower power consumption and latency has grown recently, there has grown a need for smaller and more advanced packaging techniques of semiconductor dies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of an example system that implements high bandwidth and low latency die-to-die circuit communications, in accordance with some embodiments.

FIG. 2 illustrates a block diagram of a system including multiple dies implementing the die-to-die circuit communication techniques described herein, in accordance with some embodiments.

FIG. 3 illustrates a block diagram of an example system that implements high bandwidth and low latency die-to-die circuit communications, in accordance with some embodiments.

FIG. 4 is an example flowchart of a method for configuring and implementing circuits to carry out the die-to-die circuit communication techniques described herein, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As demand for smaller and denser semiconductor devices increase, three-dimensional semiconductor devices (sometimes referred to as 3D integrated circuit, 3D ICs, 3D-ICs), which are typically constructed from multiple, stacked semiconductor dies, have emerged as an effective solution to reduce the physical area of semiconductor device. However, the use of multiple semiconductor dies introduces several challenges. One challenge relates to the distribution of clock signals across multiple dies, as each die in a multiple-die system may operate on its own clock domain, resulting in asynchronous clock relationship among dies which incurs large latency overhead to exchange data.

Various techniques may be typically employed to achieve synchronization across multiple dies, including the use of phase-locked loops (PLLs), delay-locked loops (DLLs), and clock domain crossing (CDC) circuits. However, disadvantages of existing clock signal synchronization approaches include their inability to effectively mitigate latency and low bit rate caused by the physical separation between dies and the mismatch between clock signals of different clock domains. As a result, such circuits must compromise on performance by introducing additional buffering circuit elements, resulting in increased power consumption, increased latency, and reduced data throughput.

The techniques described herein address these limitations by combining system-synchronous and source-synchronous clock operation using a synchronized PLL circuits that operate using a global clock signal of a master die as a reference clock signal. Additional delay circuits are tuned to address die-specific clock setup or hold mismatch between different clock domains, thereby optimizing both bitrate and latency without requiring additional buffering circuit elements. The techniques described herein eliminates the need for data synchronization circuits, such as de-skew first-in-first-out (FIFO) circuits that are required by conventional approaches to synchronized data received from other dies, while mitigating the latency that occurs when forwarding a global clock signal across multiple dies.

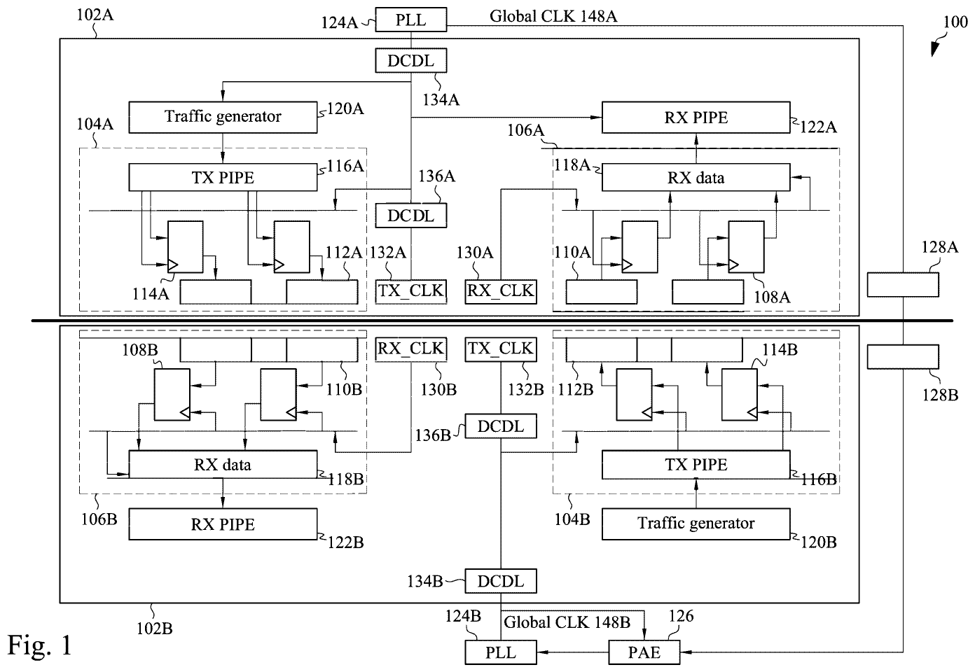

FIG. 1 illustrates a block diagram of an example system 100 that implements high bandwidth and low latency die-to-die circuit communications, in accordance with some embodiments. The system 100, or the components thereof, may include one or more logic gates and sub-circuits, each of which may be constructed from one or more logic gates. Logic gates are electronic devices that perform logical operations on one or more input signals to produce a single output signal. Various embodiments of the circuits and logic gates that implement the system 100 may include various transistors. The transistors described herein may have a certain type (n-type or p-type), but embodiments are not limited thereto. The transistors can be any suitable type of transistor including, but not limited to, metal oxide semiconductor field effect transistors (MOSFET), complementary metal oxide semiconductors (CMOS) transistors, P-channel metal-oxide semiconductors (PMOS), N-channel metal-oxide semiconductors (NMOS), bipolar junction transistors (BJT), high voltage transistors, high frequency transistors, P-channel and/or N-channel field effect transistors (PFETs/NFETs), FinFETs, planar MOS transistors with raised source/drains, nanosheet FETs, nanowire FETs, or the like.

As shown, the system 100 includes a first semiconductor die 102A and a second semiconductor die 102B (sometimes referred to as “first die 102A” and “second die 102B”, or generally as “semiconductor die(s) 102” or “die(s) 102”). In the example configuration shown in the system 100, the first die 102A is a master die, which generates a first global clock signal 148A using a first PLL 124A. Although shown outside of the boundary of the first die 102A in FIG. 1 for visual clarity, it should be understood that the first PLL 124A may be included in or otherwise defined as a circuit on the first die 102A.

The first PLL 124A can operate using a feedback mechanism to generate and synchronize an output clock signal, shown here as the global clock (CLK) 148A, with a reference clock signal. The reference clock signal can be any type of reference clock signal, such as a square wave clock signal provided via a reference clock generation circuit. The reference clock may be generated via a circuit included in the first die 102A or may be received from an external clock source in communication with the first die 102A. In some implementations, the first PLL 124A can be initialized in response to a reset signal, which may control or otherwise activate various circuits of the first die 102A.

The first PLL 124A may include a voltage-controlled oscillator (VCO), a phase detector, and a charge pump or divider circuitry. To generate the first global clock signal 148A, the VCO of the first PLL 124A can generate a free-running clock signal that is then compared against the reference clock signal by the phase detector. Differences in phase between the two signals are detected and used to adjust the frequency of the VCO through the charge pump or divider circuitry. This process continues until the first global clock signal 148A is synchronized with the reference clock signal, at which point the PLL has achieved lock, which may be indicated by a signal generated by the PLL. In some implementations, the first PLL 124A may can operate over a range of frequencies (e.g., configured via an input signal or the reference clock signal), and in some implementations the first PLL 124A may can generate the first global clock signal 148A as having a specific or predetermined frequency.

As shown, the first PLL 124A of the first die 102A can provide the first global clock signal 148A to first die-to-die clock interface circuitry 128A as well as other circuitry of the first die 102A, such as a first digitally controlled delay line (DCDL) 134A (sometimes referred to herein as “first DCDL circuit 134A or a “global DCDL 134A”). As shown, the first die-to-die clock interface circuitry 128A of the first die 102A can be electrically coupled to corresponding second die-to-die clock interface circuitry 128B of the second die 102B. The first die-to-die clock interface circuitry 128A can be used to transmit the first global clock signal 148A to components of the second die 102B. In such implementations, the first global clock signal 148A generated at the first die 102A operates as a master clock signal and the first die 102A operates as a “master die,” while the second die 102B operates as a “slave die,” in a master-slave configuration.

The first die-to-die clock interface circuitry 128A and the second die-to-die clock interface circuitry 128B can include any type of circuitry or electronic components to facilitate transfer of the first global clock signal 148A from the first die 102A to the second die 102B. For example, the first die 102A and the second die 102B may be two semiconductor wafers or dies that are bonded together through suitable bonding techniques such as, hybrid bonding, micro bumps, direct bonding, chemically activated bonding, plasma activated bonding, anodic bonding, eutectic bonding, glass frit bonding, adhesive bonding, thermo-compressive bonding, reactive bonding and/or the like. The first die-to-die clock interface circuitry 128A and the second die-to-die clock interface circuitry 128B can provide an electrical connection between the stacked semiconductor dies using a number of through via structures, such as through substrate vias (TSV) (e.g., through silicon vias), wire bonding, micro-bumps, through-die vias (TDVs), or the like.

As shown, the first global clock signal 148A generated using the first PLL 124A is provided as input to a phase aligned element 126. The phase aligned element 126 can include circuitry and other components that generate an aligned reference clock signal using feedback from a second PLL 124B of the second die 102B. The second PLL 124B can be similar to, and include any of the structure and functionality of, the first PLL 124A of the first die 102A. The second PLL 124B can generate a second global clock signal 148B, which is provided to various circuits/components present on the second die 102B. As shown, the second global clock signal 148B generated by the second PLL 124B can be provided as a second input to the phase aligned element 126.

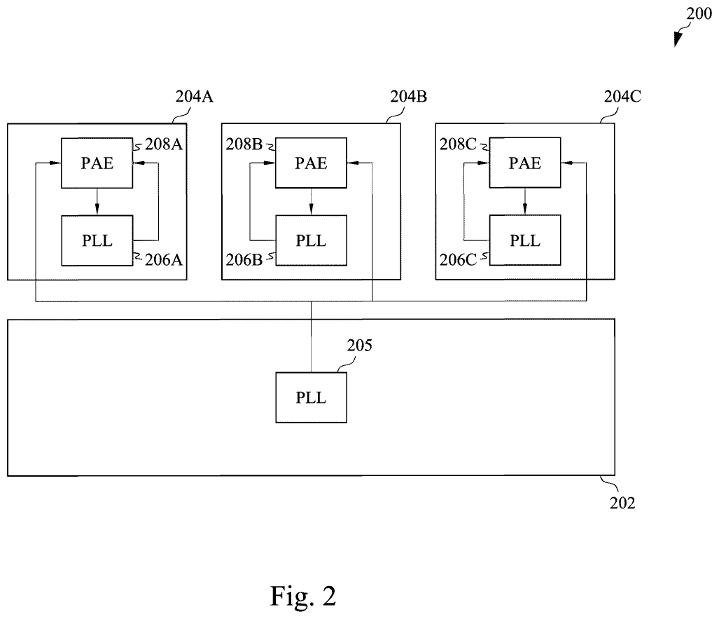

The phase aligned element 126 can receive both the first global clock signal 148A generated by the first PLL 124A and the generated second global clock signal 148B as input, to generate an aligned reference clock signal for the second PLL 124B. The aligned reference signal can be used to adjust the phase of the second global clock signal 148B, such that the phases of the first global clock signal 148A and the second global clock signal 148B are aligned. The use of the phase aligned element 126 enables the second die 102B to generate the second global clock signal 148B, which is automatically aligned with the first global clock signal 148A of the first die 102A. This approach enables further dies to generate clock signals that are all phase-aligned with the global clock signal of a master die (e.g., the first die 102A), as described in further detail in connection with FIG. 2.

Each of the first die 102A and the second die 102B may include any number of components or circuits, including but not limited to system-on-chip (SoC) components, processing components (e.g., adders, multipliers, arithmetic logic units, etc.), memory circuits, logic gates, components, or circuits, data transfer circuits, or any other type of computational component. In some implementations, the first die 102A and the second die 102B may include high-performance computing circuits, such as parallel processing elements for graphics processing units (GPUs), compute-in-memory (CIM) circuits, or other computing circuitry. In addition to such components and circuits, the first die 102A is shown as including circuitry to transmit and receive data to and from the second die 102B, including a first transmitter circuit 104A and a first receiver circuit 106A.

The first transmitter circuit 104A is shown as including a first transmission pipeline circuit 116A (sometimes referred to as a “first transmission pipeline 116A”), one or more first transmission flip-flops 114A, and first die-to-die transmission interface circuitry 112A. The first die-to-die transmission interface circuitry 112A can enable transmission of the data generated or accessed at the first die 102A to the second die 102B. The first die-to-die transmission interface circuitry 112A of the first die 102A can be electrically coupled to corresponding second die-to-die receiver interface circuitry 110B of the second die 102B. The first die-to-die transmission interface circuitry 112A can include, but is not limited to, TSVs, wire bonding points, micro-bumps, TDVs, or the like.

As shown, transmission data using the first die-to-die transmission interface circuitry 112A is provided by the one or more first transmission flip-flops 114A. The first transmission flip-flops 114A can include any type of flip-flop, latch, or clocked memory element that can store data according to setup/hold constraints of the first die-to-die transmission interface circuitry 112A and the second die-to-die receiver interface circuitry 110B of the first die 102A and the second die 102B, respectively. In some implementations, the first transmission flip-flops 114A may form a register with a predetermined bit width. Any number of first transmission flip-flops 114A may be included in the first transmitter circuit 104A to provide a transmission bus having any number of bits.

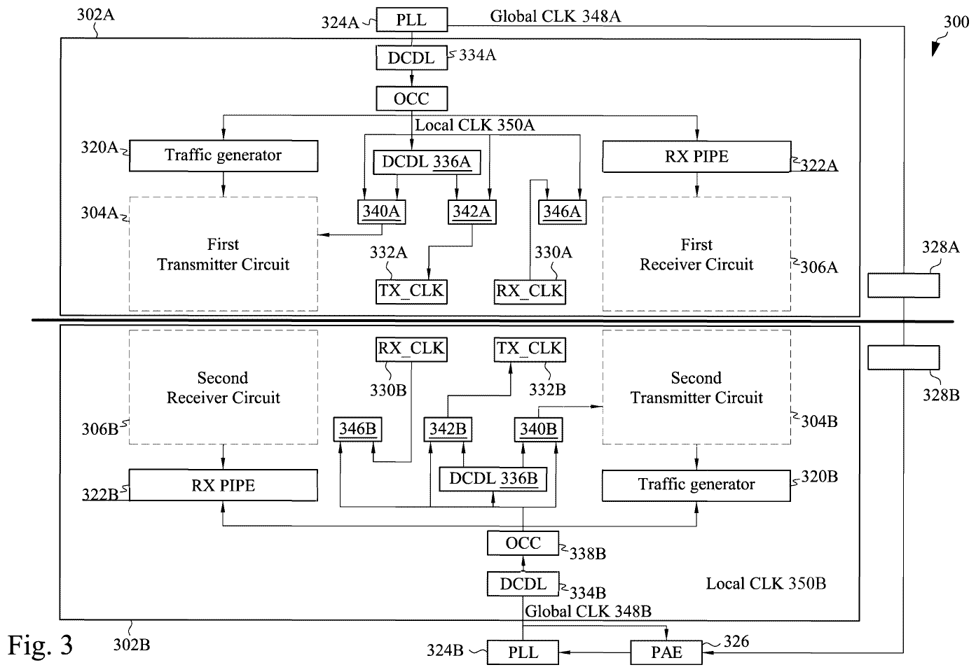

Each of the first transmission flip-flops 114A may receive a local clock signal generated by the first DCDL 134A of the first die 102A, as shown. The first DCDL 134A of the first die 102A can be used, in connection with a local DCDL 136A of the first die 102A, in a two-phase clock tuning process to reduce inter-die skew. Further details of the 2-phase clock tuning approach are described in connection with FIG. 3. The first DCDL 134A (sometimes referred to as a “first global DCDL 134A” of the first die 102A can be used, for example, to match the clock latency between the path from the first global clock signal 148A to the first die-to-die clock transmission interface circuitry 132A and the path from the second global clock signal 148B to the second die-to-die clock transmission interface circuitry 132B.

The first DCDL 134A can include any type of digital circuit that enables control over signal timing by adjusting the propagation delay through a series of circuit elements, such as flip-flops or latches. Any suitable type of circuit delay element may be included in the first DCDL 134A, including analog-tunable delay elements and digitally controlled delay elements. The first DCDL 134A may be programmable, for example, by a control circuit. The control circuit may be part of the first die 102A or may be external to the first die 102A. The first DCDL 134A can include any type of delay circuit, including ring-oscillator-based delay lines, PLL-based delay lines, tapped delay lines, or switched capacitor delay lines, among others. The latency of the above paths can be matched by sweeping the delay from the lowest potential delay to the largest potential delay, until the latencies of the above paths of each die are matched.

In addition to receiving a local clock signal from the first DCDL 134A, the first transmission flip-flops 114A receive data input from the first transmission pipeline 116A. The first transmission pipeline 116A can include any type of memory elements that can store and arrange data provided by a first traffic generator 120A for transmission via the first die-to-die transmission interface circuitry 112A. For example, the first transmission pipeline 116A may include any number of flip-flops, latches, or other memory elements to enqueue data for transmission from the first die 102A to the second die 102B. The data to be transmitted can be provided via the first traffic generator 120A.

The first traffic generator 120A can include any type of circuit, logic component, or device that can generate traffic for performing the various clock and delay synchronization techniques described herein. In some implementations, the first traffic generator 120A can include logic components that automatically generates a predetermined pattern of data. The first traffic generator 120A can generate the data for transmission to the second die 102B, which can include checksum verification logic (e.g., as part of or coupled to a second receiver pipeline circuit 122B described in further detail herein) to verify that data is properly transferred (e.g., without errors or corruption) between the first die 102A and the second die 102B.

As shown, the first traffic generator 120A and the first transmitter circuit 104A can each receive the local clock signal generated by the first DCDL 134A. Additionally, the local clock signal can be provided to a first receiver pipeline circuit 122A and a first receiver circuit 106A. The first receiver pipeline circuit 122A can receive from the first receiver circuit 106A. The first receiver pipeline circuit 122A can include any number of memory elements, including but not limited to flip-flops, latches, static random-access memory, or dynamic random-access memory. In some implementations, the first receiver pipeline circuit 122A can be coupled to one or more circuits that store, process, or transport the data received from the first receiver circuit 106A.

The first receiver circuit 106A is shown as including any number first die-to-die receiver interface circuitry 110A, one or more first receiver flip-flops 108A, and a first receiver data register 118A. The first die-to-die receiver interface circuitry 110A can receive data generated and transmitted from the second die 102B. The first die-to-die receiver interface circuitry 110A of the first die 102A can be electrically coupled to corresponding second die-to-die transmission interface circuitry 112B of the second die 102B. The first die-to-die transmission interface circuitry 112A can include, but is not limited to, TSVs, wire bonding points, micro-bumps, TDVs, or the like. As shown, the first die-to-die receiver interface circuitry 110A is electrically coupled to the first receiver flip-flops 108A.

The first receiver flip-flops 108A are shown as receiving a clock signal from first die-to-die clock receiver interface circuitry 130A, described in further detail herein. The first receiver flip-flops 108A can include any type of flip-flop, latch, or clocked memory element that can store data according to setup/hold constraints of the first die-to-die receiver interface circuitry 110A and the second die-to-die transmission interface circuitry 112B of the first die 102A and the second die 102B, respectively. In some implementations, the receiver flip-flops 108A may form a register with a predetermined bit width. Any number of receiver flip-flops 108A may be included in the first receiver circuit 106A to provide a transmission bus having any number of bits. The number of receiver flip-flops 108A can be equal to the number of corresponding second transmission flip-flops 114B of the second transmitter circuit 104B of the second die 102B.

The receiver flip-flops 108A can receive and store data from the first die-to-die receiver interface circuitry 110A according to the clock signal received from the first die-to-die clock receiver interface circuitry 130A. Data stored in the first receiver flip-flops 108A can be provided to a first receiver data register 118A of the first receiver circuit 106A. The first receiver data register 118A can include any type of memory elements that store the data received via the receiver flip-flops 108A, such as flip-flops, latches, static random-access memory, or dynamic random-access memory, among others. As shown, the first receiver data register 118A can receive the same clock signal as the first receiver flip-flops 108A, from the first die-to-die clock receiver interface circuitry 130A. Data stored in the first receiver data register 118A can be captured by the receiver pipeline circuit 122A.

The receiver pipeline circuit 122A can include a pipeline of registers or other memory elements that receive the local clock signal generated by the first DCDL 134A. The memory elements in the receiver pipeline circuit 122A can capture the data in the first receiver data register 118A, provided in the clock domain of the clock signal of the first die-to-die clock receiver interface circuitry 130A, in a system-synchronous arrangement. As described in further detail herein, the clock signal received via the first die-to-die clock receiver interface circuitry 130A is synchronized with the local clock signal generated by the first DCDL 134A, thereby obviating the need for additional buffer circuitry to asynchronously transfer data between clock domains. Data captured using the receiver pipeline circuit 122A can be directly accessed or otherwise processed by other components of the first die 102A. In some implementations, the receiver pipeline circuit 122A can include a checksum verification circuit, such as a cyclic redundancy check (CRC) circuit.

To ensure that the clock signals used by the receiver circuits (e.g., the first receiver circuit 106A of the first die 102A and the second receiver circuit 106B of the second die 102B) are synchronized with the local clock of the respective die, an additional delay circuit can be utilized in a source-synchronization configuration. As shown, first die-to-die clock transmission interface circuitry 132A receives a clock signal generated by a local DCDL circuit 136A (sometimes referred to as a “local DCDL 136A” or a “first local DCDL 136A”) of the first die 102A. The first die-to-die clock transmission interface circuitry 132A can include, but is not limited to, one or more TSVs, one or more wire bonding points, one or more micro-bumps, one or more TDVs, or the like. As shown, the first die-to-die clock transmission interface circuitry 132A provides a forwarded clock signal to corresponding second die-to-die clock receiver interface circuitry 130B of the second die 102B.

The clock signal forwarded via the first die-to-die clock transmission interface circuitry 132A and received by the corresponding second die-to-die clock receiver interface circuitry 130B, can be generated by the local DCDL circuit 136A of the first die 102A. The local DCDL circuit 136A can be similar to the first DCDL circuit 134A. The local DCDL 136A may be programmable, for example, by a control circuit. The control circuit may be part of the first die 102A or may be external to the first die 102A. The local DCDL 136A can include any type of delay circuit, including ring-oscillator-based delay lines, PLL-based delay lines, tapped delay lines, or switched capacitor delay lines, among others.

The local DCDL 136A can be tuned or otherwise programmed to provide a suitable delay to enable a source-synchronization configuration for data transfer between the first die 102A and the second die 102B. Using source-synchronization configuration for data transfer can cancel out the clock and data die-to-die propagation delay, thereby enabling higher bitrate transfer compared to other solutions. Further details of tuning/adjusting the first DCDL 134A and the local DCDL 136A are described in connection with FIG. 3.

The second die 102B includes similar components and structures as the first die 102A. The second die 102B is shown as including a second receiver circuit 106B (electrically coupled to the first transmitter circuit 104A), a second transmitter circuit 104B (electrically coupled to the first receiver circuit 106A), a second receiver pipeline circuit 122B, a second traffic generator 120B, a second global DCDL circuit 134B, and a second local DCDL circuit 136B. The second die 102B includes second die-to-die clock receiver interface circuitry 130B (electrically coupled to the first die-to-die clock transmission interface circuitry 132A) and second die-to-die clock transmission interface circuitry 132B (electrically coupled to the first die-to-die clock receiver interface circuitry 130A).

The second receiver circuit 106B (and the components thereof) can include any of the structure and functionality of the first receiver circuit 106A. For example, the second receiver circuit 106B includes a second receiver data register 118B, one or more receiver flip-flops 108B, and second die-to-die receiver interface circuitry 110B, which can be similar to the first receiver data register 118A, the receiver flip-flops 108A, and the first die-to-die receiver interface circuitry 110A of the first receiver circuit 106A. The second receiver circuit 106B can receive data from the first transmitter circuit 104A according to the techniques described herein.

Data to be transmitted by the second transmitter circuit 104B can be generated by the second traffic generator 120B, which may be similar to and include any of the structure and functionality of the first traffic generator 120A. Data received by the second receiver circuit 106B can be captured by the second receiver pipeline circuit 122B, which may be similar to and include any of the structure and functionality of the first receiver pipeline circuit 122A. The second die 102B can include a second DCDL circuit 134B, which may be programmable and generate a local clock signal that matches latency between the forwarded transmission clocks (e.g., provided via the first and second die-to-die clock transmission interface circuitry 132A and 132B) are matched with one another, as described in further detail in connection with FIG. 3.

The second die 102B is shown as including a second DCDL circuit 136B, which can be similar to and include any of the structure or functionality of the local DCDL circuit 136A. The local DCDL 136A can be tuned or otherwise programmed to provide a suitable delay to enable a source-synchronization configuration for data transfer between the second die 102B and the first die 102A. Using source-synchronization configuration for data transfer can cancel out the clock and data die-to-die propagation delay, thereby enabling higher bitrate transfer compared to other solutions. Further details of tuning/adjusting the first local DCDL 136A and the second local DCDL 136B are described in connection with FIG. 3.

In some implementations, each of the first and second DCDL circuits 134A, 134B and the first and second local DCDL circuits 136A, 136B of the first and second dies 102A and 102B can include persistent memory elements that, when configured according to the techniques described herein, can remain in the same programmed state even in the event of power-off or reset events of the first and/or second dies 102A and 102B. For example, the first and second DCDL circuits 134A, 134B and the first and second local DCDL circuits 136A, 136B of the first and second dies 102A and 102B can include eFuse memory, flash memory, or other persistent memory elements that maintain their state even when power is removed from the circuits. This enables the latency and bit rate of data transfer between the first die 102A and the second die 102B to be configured a single time (e.g., during device manufacture, during a device configuration step, etc.), without requiring further clock synchronization configuration operations.

Although the foregoing description details an example that includes two separate dies (e.g., the first die 102A and the second die 102B), it should be understood that the techniques described herein may be implemented with any number of dies, each of which may any of the components described in connection with the first die 102A and the second die 102B. Additionally, each of the first die 102A and the second die 102B can include any number of circuits that use the data communicated between dies, in addition to any processing, memory, or data transmission operations that can be performed using semiconductor devices. Each additional processing circuit of the first and second dies 102A and 102B may receive, for example, the first global clock signal 148A and the second global clock signal 148B generated by the first PLL 124A and the second PLL 124B, respectively, or the local clock signals generated by the first DCDL 134A of the first die 102A and the second DCDL 134B of the second die 102B, respectively.

FIG. 2 illustrates a block diagram of a system including multiple dies implementing the die-to-die circuit communication techniques described herein, in accordance with some embodiments. The system 200, in this example, is shown as including a primary die 202. The primary die 202 is shown as being in communication with three secondary dies 204A, 204B, and 204C (sometimes referred to herein as “secondary die(s) 204”). The primary die 202 may be similar to and include any of the structure and implement of functionality of the first die 102A of FIG. 1. The primary die 202 is shown as including a primary PLL 205, which may be similar to the first PLL 124A of FIG. 1.

In the system 200, the primary PLL 205 of the primary die 202 can provide a clock signal (e.g., the first global clock signal 148A, etc.) to each of the secondary dies 204. To do so, the primary die 202 can include clock transmission interface circuitry (e.g., the first die-to-die clock interface circuitry 128A) for each of the secondary dies 204, each of which can include corresponding clock receiver circuitry (e.g., second die-to-die clock interface circuitry 128B) that receives the clock signal and provides the clock signal to the phase alignment element (e.g., the phase alignment elements 208A, 208B, and 208C).

The secondary dies 204A, 204B, and 204C are shown as including the phase alignment elements 208A, 208B, and 208C (sometimes referred to as the “phase alignment element(s) 208”) and the secondary PLLs 206A, 206B, and 206C (sometimes referred to as the “secondary PLL(s) 206”), respectively. The phase alignment elements 208 can be similar to and include any of the structure and functionality of the phase aligned element 126. For example, the phase alignment elements 208 can include circuitry and other components that generate an aligned reference clock signal using feedback from the corresponding secondary PLLs 206 of the secondary dies 204.

The aligned reference clock signal is then provided as input to the secondary PLLs 206, which generate a respective global clock signal at each of the secondary dies 204. The phase alignment element 208 enables generation of a respective global clock signal with a phase that is automatically aligned and locked to the phase of the global clock signal provided by the primary PLL 205. The use of the phase alignment obviates the requirement of using additional buffer circuitry to compensate for misaligned clocks distributed from a single primary die to multiple secondary dies. Although three secondary dies 204 are shown in the system 200, it should be understood that any number of secondary dies 204 may be in communication with a primary die 202. Further, although all secondary dies 204 are shown as occupying a single layer, it should be understood that the primary die 202 and the secondary dies 204 may be arranged in any suitable configuration to implement any type of 3D-IC.

As each of the secondary dies generates its own global clock signal that is automatically aligned with the primary clock signal of the primary die 202, the system 200 can implement a hybrid system-synchronous and source-synchronous clock domain-transfer approach, while maximizing data throughput and minimizing latency. Further details of specific tuning techniques for various delay circuits (e.g., the first and second DCDL circuits 134A, 134B, 136A, and 136B) used to mitigate the effects of propagation delay are described in connection with FIG. 3.

FIG. 3 illustrates a block diagram of an example system 300 that implements high bandwidth and low latency die-to-die circuit communications, in accordance with some embodiments. The system 300, or components thereof, may include one or more logic gates and sub-circuits, each of which may be constructed from one or more logic gates. Logic gates are electronic devices that perform logical operations on one or more input signals to produce a single output signal. Various embodiments of the circuits and logic gates that implement the system 300 may include various transistors. The transistors described herein may have a certain type (n-type or p-type), but embodiments are not limited thereto. The transistors can be any suitable type of transistor including, but not limited to, MOSFET, CMOS transistors, PMOS, NMOS, BJT, high voltage transistors, high frequency transistors, PFETs/NFETs, FinFETs, planar MOS transistors with raised source/drains, nanosheet FETs, nanowire FETs, or the like.

The system 300 of FIG. 3 can be similar to, and include any of the structure, components, and implement any of the functionality of, the system 100 of FIG. 1. The system 300 is shown as including a first die 302A (which may be similar to and include any of the structure of the first die 102A) in communication with a second die 302B (which may be similar to and include any of the structure of the first die 102A).

In the example configuration shown in the system 100, the first die 302A is a master die (or primary die), which generates a first global clock signal 348A using a first PLL 324A. Although shown outside of the boundary of the first die 302A in FIG. 3 for visual clarity, it should be understood that the first PLL 324A may be included in or otherwise defined as a circuit on the first die 302A. The first PLL 324A may be similar to, and include any of the structure and functionality of, the first PLL 124A of FIG. 1.

The first PLL 324A can operate using a feedback mechanism to generate and synchronize an output clock signal, shown here as the global clock (CLK) 348A, with a reference clock signal. The reference clock signal can be any type of reference clock signal, such as a square wave clock signal provided via a reference clock generation circuit. The reference clock may be generated via a circuit included in the first die 302A or may be received from an external clock source in communication with the first die 302A. In some implementations, the PLL 324A can be initialized in response to a reset signal or in response to a signal from control circuitry, which may control or otherwise activate various circuits of the first die 302A.

As shown, the first PPL 324A of the first die 302A can provide the first global clock signal 348A to first die-to-die clock interface circuitry 328A as well as other circuitry of the first die 302A, such as a first global DCDL 334A. The first die-to-die clock interface circuitry 328A and the first global DCDL 334A can be similar to and may include any of the structure or functionality of, the first die-to-die clock interface circuitry 128A and the first DCDL 134A, respectively. As shown, the first die-to-die clock interface circuitry 328A of the first die 302A can be electrically coupled to corresponding second die-to-die clock interface circuitry 328B of the second die 302B. The first die-to-die clock interface circuitry 328A can be used to transmit the first global clock signal 348A to components of the second die 302B, as described herein.

As shown, the first global clock signal 348A generated using the first PLL 324A is provided as input to a phase aligned element 326. The phase aligned element 326 can be similar to and perform any of the functionality of the phase aligned element 126 of FIG. 1, and the second PLL 324B can be similar to, and include any of the structure and functionality of, the second PLL 124B of FIG. 1. The second PLL 324B can generate a second global clock signal 348B, which is provided to various circuits/components present on the second die 302B. As shown, the second global clock signal 348B generated by the second PLL 324B can be provided as a second input to the phase aligned element 326, as described herein, causing the second PLL 324B to produce a second global clock signal 348B having the same phase as the first global clock signal 348A.

Each of the first die 302A and the second die 302B are shown as including similar components as the first die 102A and the second die 102B of FIG. 1. The first die 302A is shown as including a first transmitter circuit 304A and a first receiver circuit 306A, which may include any of the components of, and perform any of the functionality of, the first transmitter circuit 104A and the first receiver circuit 106A. Data transmitted by the first transmitter circuit 304A may be provided by the first traffic generator 320A, which may be similar to the first traffic generator 120A of FIG. 1. Data received by the first receiver circuit 306A may be captured by the first receiver pipeline circuit 322A, which may be similar to the first receiver pipeline circuit 122A of FIG. 1.

Corresponding components can be present on the second die 302B, as described herein. The second die 302B is shown as including a second transmitter circuit 304B and a second receiver circuit 306B, which may include any of the components of, and perform any of the functionality of, the second transmitter circuit 104B and the second receiver circuit 106B. Data transmitted by the second transmitter circuit 304B may be provided by the second traffic generator 320B, which may be similar to the second traffic generator 120B of FIG. 1. Data received by the second receiver circuit 306B may be captured by the second receiver pipeline circuit 322B, which may be similar to the first receiver pipeline circuit 122B of FIG. 1.

As described herein, the first transmitter circuit 304A can be in electrical communication with, and transmit data to, the corresponding second receiver circuit 306B, and the second transmitter circuit 304B can be in electrical communication with, and transmit data to, the corresponding first receiver circuit 306A. Like the first die 102A and the second die 102B of FIG. 1, the first die 302A and the second die 302B can be in electrical communication with one another using interface circuitry, which may include, but is not limited to, TSVs, wire bonding, or TDVs, among others.

As described herein, a forwarded clock signal used by the first receiver circuit 306A can be provided via second die-to-die clock transmission interface circuitry 332B of the second die 302B and received via first die-to-die clock receiver interface circuitry 330A of the first die 302A, each of which may be similar to the second die-to-die clock transmission interface circuitry 132B and the first die-to-die clock receiver interface circuitry 130A of FIG. 1, respectively. Similarly, a forwarded clock signal used by the second receiver circuit 306B can be provided via die-to-die clock transmission interface circuitry 330A of the first die 302A and received via the second die-to-die clock receiver interface circuitry 330B of the second die 302B, each of which may be similar to the first die-to-die clock transmission interface circuitry 132A and the second die-to-die clock receiver interface circuitry 130B of FIG. 1, respectively.

The configuration shown in the system 300 can be used to tune or otherwise adjust each of the first and second global DCDL circuits 334A and 334B (sometimes referred to as “global DCDL circuits 334A and 334B”, “global DCDL circuit(s) 334”, or “global DCDL(s) 334”) of the first and second dies 302A and 302B, respectively, and the local DCDL circuits 336A and 336B of the first and second dies 302A and 302B, respectively. As shown, in some implementations, the first die 302A and the second die 302B can include on-chip clock correction (OCC) circuits 338A and 338B (sometimes generally referred to as the “OCC circuit(s) 338”), respectively. As the clock paths produced by the global DCDL circuits 334 may be relatively large, duty cycle distortion may occur. To correct these issues, the OCC circuits 338 can be used to generate the first and second local clock signals 350A and 350B for the first and second dies 302A and 302B, respectively, which have corrected duty cycles. The OCC circuits 338 may include one or more clock divider circuits that receive the outputs of the global DCDLs 334 and generate the first and second local clock signals 350A and 350B as output. In some implementations, the OCC circuits 338 can include delay circuit elements that adjust the timing of the rising and falling edges of the input clock signal, thereby correcting an imbalance in the duty cycle caused by signal propagation delays.

As shown, the first local clock signal 350A can be provided to the first traffic generator 320A, the first receiver pipeline circuit 322A, and to additional delay components of the first die 302A, shown here as the second local DCDL 336B, the first multiplexer 340A, and the second multiplexer 342A. Similarly, the second local clock signal 350B can be provided to the second traffic generator 320B, the second receiver pipeline circuit 322B, and to additional delay components of the second die 302B, shown here as the second local DCDL 336B, the first multiplexer 340B, and the second multiplexer 342B. Each of the delay elements can be controlled, for example, according to input from a control circuit of the first die 302A and/or the second die 302B, to create any needed delay for the first and second local clock signals 350A and 350B to maximize transfer bitrate while minimizing system latency.

In an example configuration process, the various delay elements of the first die 302A and the second die 302B can be adjusted in two stages. Each of the delay elements described herein may be adjusted by control circuitry of the first die 302A, the second die 302B, or by external control circuitry in communication with the first die 302A and/or the second die 302B. In the first stage of the tuning process, the global DCDLs 334A and 334B can be iteratively tuned such that the clock latency of the first and second local clock signals 350A and 350B from the OCC circuits 338A and 338B, respectively, to the first and second die-to-die clock transmission interface circuitry 332A and 332B, respectively, and equal to one another.

As described herein in connection with the first and second DCDLs 134A and 134B of FIG. 1, the global DCDLs 334A and 334B can include programmable delay elements that are capable of applying a set of predetermined delays to an input clock signal. Programming or otherwise adjusting the global DCDLs 334A and 334B can performed once the first and second PLLs 324A and 324B are each locked and producing phase-aligned global clock signals 348A and 348B. In the first stage, each of the global DCDLs 334A and 334B can be iteratively adjusted (e.g., with a sweep across all programmable settings) until the clock latency from the first PLL 324A to the first die-to-die clock transmission interface circuitry 332A matches the clock latency from the second PLL 324B to the second die-to-die clock transmission interface circuitry 332B in the first die 302A and the second die 302B, respectively.

In some implementations, the latency may be monitored by control circuitry in communication with the first die 302A and the second die 302B. In the first stage, the second multiplexers 342A and 342B of the first and second dies 302A and 302B, respectively, can each be in a first state, such that the output of the OCC circuits 338A and 338B each pass directly to the first and second die-to-die clock transmission interface circuitry 332A and 332B, respectively. The states of the second multiplexers 342A and 342B may be controlled, for example, using corresponding signals generated by control circuitry in communication with the first and second dies 302A and 302B. The states of the third multiplexers 346A and 346B may be controlled, for example, using corresponding signals generated by control circuitry in communication with the first and second dies 302A and 302B, such that the third multiplexers 346A and 346B each provide the first and second local clock signals 350A and 350B to the first receiver circuit 306A and the second receiver circuit 306B, respectively. The first tuning stage can therefore be performed in a system-synchronous mode. The global DCDLs 334A and 334B can each be adjusted such that the minimum possible delay is selected while still matching the latency of the clock path between each of the first and second dies 302A and 302B, with the objective of delaying a die having a faster global clock trunk.

Once the global DCDLs 334A and 334B have been adjusted, a second tuning stage can adjust each of the first and second local DCDLs 336A and 336B (sometimes referred to as the “local DCDL(s) 336A and 336B”, “local DCDL circuit(s) 336A and 336B” or the “local DCDL(s) 336”). The local DCDLs 336 can be adjusted in a source-synchronous mode to further boost bitrate, while minimizing overall system latency. Any of the first multiplexers 340A and 340B, the second multiplexers 342A and 342B, the third multiplexers 346A and 346B, and the local DCDLs 336A and 336B can be activated, deactivated, or adjusted to perform the second tuning step. The second tuning step can be used to compensate for worst case corner variation between the first and second local clock signals 350A and 350B and the forwarded clocks received via the first and second die-to-die clock receiver interface circuitry 330A and 330B, respectively.

To perform the second tuning step, the third multiplexers 346A and 346B can each be switched into a source-synchronous mode, in which the clock signals received from the first and second die-to-die clock receiver interface circuitry 330A and 330B are provided as input to the first and second receiver circuits 306A and 306B, respectively. Once in the source-synchronous mode has been activated, one or more of the first multiplexers 340A and 340B, the second multiplexers 342A and 342B, and the local DCDLs 336A and 336B can be activated, deactivated, or adjusted to minimize local clock skew in the source-synchronous mode across the first die 302A and the second die 302B.

The first multiplexers 340A and 340B can be activated to cause the local DCDLs 336A and 336B to be applied to the first and second transmitter circuits 304A and 304B (e.g., delaying launch of data to address skew), respectively, and the second multiplexers 342A and 342B can be activated to cause the local DCDLs 336A and 336B to be applied to the second and first receiver circuits 306B and 306A, respectively (e.g., delaying capture of data at opposite die 302 to address skew). For example, if the clock skew causes a setup violation at the second receiver circuit 306B of the second die 302B, the second multiplexer 342A can be activated, and the delay of the local DCDL 336A of the first die 302A can be adjusted according to control inputs (e.g., determined via sweeping to optimize transfer bitrate) to address the clock skew. Similar adjustments of the second multiplexer 342B and the second local DCDL 336B can be performed at the second die 302B if a setup violation is detected at the first die 302A.

In another example, if the clock skew causes a hold violation at the first transmitter circuit 304A of the first die 302A, the first multiplexer 340A can be activated, and the delay of the local DCDL 336A of the first die 302A can be adjusted according to control inputs (e.g., determined via sweeping to optimize transfer bitrate) to address the clock skew mismatch. Similar adjustments of the first multiplexer 340B and the local DCDL 336B can be performed at the second die 302B if a hold violation is detected at the second transmitter circuit 304B of the second die 302B.

Tuning the global DCDLs 334 and the local DCDLs 336 can be performed, in some implementations, by iteratively applying one of a set of predetermined delay inputs to a given DCDL to select a delay to evaluate. Each DCDL described herein may be controlled via one or more control registers, which enable programmable delays by establishing predetermined circuit paths through predetermined numbers of delay circuit elements. The DCDLs described herein may include any suitable delay resolution, such as a four-bit resolution, a six-bit resolution, or an eight-bit resolution, among others.

Once the global DCDLs 334 and the local DCDLs 336 have been tuned, the configuration values for each DCDL can be stored in memory and applied to the configuration input of the global DCDLs 334 and the local DCDLs 336, thereby fixing the delay following configuration. Similar control inputs can be stored and applied for each of the first multiplexers 340A and 340B, the second multiplexers 342A and 342B, and the third multiplexers 346A and 346B. Using the aforementioned clock paths and delay circuits, the system 300 can implement a hybrid system-synchronous and source-synchronous clock distribution scheme across an arbitrary number of semiconductor dies. It should be understood that although two dies are described in connection with this example, that any number of semiconductor dies may be synchronized with one other using the techniques described herein, including an arrangement similar to that shown in FIG. 2.

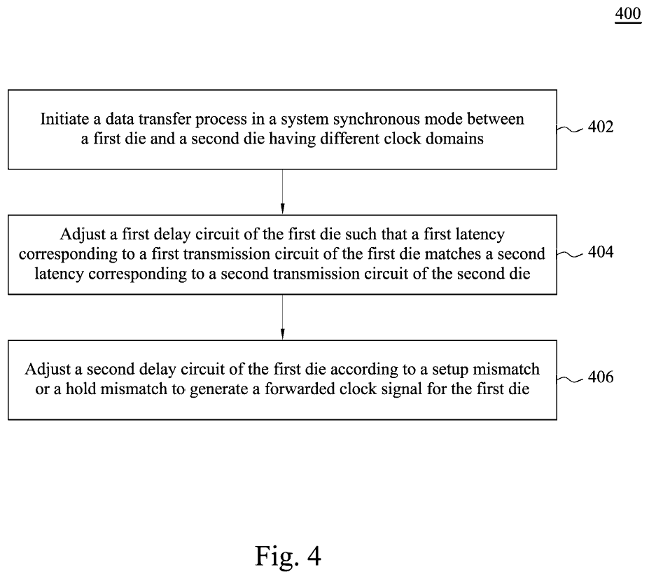

FIG. 4 is an example flowchart of a method 400 for configuring and implementing circuits to carry out the die-to-die circuit communication techniques described herein, in accordance with some embodiments. It should be noted that the method 400 is merely an example and is not intended to limit the present disclosure. Accordingly, it is understood that the order of operation of the method 400 of FIG. 4 can change, that additional operations may be provided before, during, and after the method 400 of FIG. 4, and that some other operations may only be described briefly herein.

The method 400 starts with operation 402, in which a data transfer process in a system synchronous mode is initiated between a first die (e.g., the first die 102A, 202, 302A) and a second die (e.g., the second die 102B, 204, 302B) having different clock domains. In some implementations, the first die can be a master/primary die and a second die can be a slave/secondary die. The first die can use a first PLL (e.g., first PLL 124A, 324A) to generate a first global clock signal (e.g., the first global clock signal 148A), which is provided to the second die. The second die can generate a second global clock signal using a phase aligned element (e.g., the phase aligned element 126, the phase aligned element 326) and a second PLL (the second PLL 124B, second PLL 324B).

The system-synchronous mode can be initiated by adjusting the state of one or more multiplexers (e.g., the first multiplexers 340A and 340B, the second multiplexers 342A and 342B, the third multiplexers 346A and 346B) of the first and second dies to distribute the respective global clock signals to each of the components of the respective dies. In some implementations, the global clock signals may be provided as input to respective OCC circuits (e.g., the OCC circuits 338A, 338B) of the first and second dies. The output of the OCC circuits can be provided to a transmitter circuit (e.g., the first and second transmitter circuits 304A, 304B) and a receiver circuit (e.g., the first and second receiver circuits 306A, 306B) of the first and second dies in the system-synchronous mode. Data transfer can be initiated by activating data from a traffic generator (e.g., the first traffic generator 120A, 320A) of one or more of the first and second dies.

The method 400 continues with operation 404, in which a first delay circuit (e.g., the first global DCDLs 134A, 334A) of the first die is adjusted to match a first latency to a first transmission circuit of the first die and a second latency to a second transmission circuit of the second die. In some implementations, the latency can be optimized by monitoring the bitrate of the data transfer process, and selecting one of a set of predetermined delay values for the delay circuit that optimizes an initial bitrate from the first die to the second die. In some implementations, the latency can be monitored by measuring the clock skew difference between the first die and the second die. The clock skew of a first path from the first PLL of the first die to a first clock transmission interface (e.g., the first die-to-die clock transmission interface circuitry 132A, 332A) and a second path from the second PLL of the second die to a second clock transmission interface (e.g., the second die-to-die clock transmission interface circuitry 132B, 332B).

In some implementations, the global delay circuits at the first or second die can be adjusted according to whether the first die is delayed (e.g., slower) than the clock at the second die or ahead of (e.g., faster) than the clock at the second die, along the aforementioned paths. In some implementations, if the first global clock at the first die is faster than the second global clock at the second die, the first global delay circuit of the first die can be activated and adjusted to address the skew. In some implementations, if the second global clock at the second die is faster than the first global clock at the first die, the second global delay circuit of the second die can be activated and adjusted to address the skew.

The method 400 continues with operation 406, in which a second delay circuit (e.g., the first local DCDLs 136A, 336A) of the first die is adjusted according to a setup mismatch or a hold mismatch to generate a forwarded clock signal for the first die. Prior to adjusting or activating the second delay circuit, the first die and the second die can be configured to operate in a source-synchronous mode. To do so, multiplexers (e.g., the third multiplexers 346A, 346B) at the first and second dies can be configured to change state to such that a first receiver circuit (e.g., the first receiver circuit 306A) of the first die receives a forwarded clock signal from the second die, and a second receiver circuit (e.g., the second receiver circuit 306B) of the second die receives a forwarded clock signal from the first die.

Once the source-synchronous mode has been configured, local delay circuits at the first and/or second die can be selectively applied to address any detected setup or hold violations. To activate the local delay circuits, additional multiplexers (e.g., the first multiplexers 340A, 340B, the second multiplexers 342A, 342B) can be selectively activated to address setup/hold violations at each die. For example, if the clock skew causes a setup violation at the second receiver circuit of the second die, a multiplexer (e.g., the second multiplexer 342A) at the first die can be activated to apply delay of a local delay circuit (e.g., the first local DCDL 336A) of the first die. The local delay circuit can be adjusted according to control inputs (e.g., determined via sweeping to optimize transfer bitrate) to address the clock skew. Similar adjustments of a corresponding multiplexer (e.g., the second multiplexer 342B) and delay circuit (e.g., the local DCDL 336B) can be performed at the second die if a setup violation is detected at the first receiver circuit of the first die.

In another example, if the clock skew causes a hold violation at a first transmitter circuit of the first die, another multiplexer (e.g., the first multiplexer 340A) can be activated and the delay circuit (e.g., the first local DCDL 336A) of the first die 302A can be applied to the input clock signal for the first transmitter circuit. As described herein, the local delay circuit can be adjusted according to control inputs (e.g., determined via sweeping to optimize transfer bitrate) to address the clock skew mismatch. Similar adjustments of another corresponding multiplexer (e.g., the first multiplexer 340B) and delay circuit (e.g., the local DCDL 336B) can be performed at the second die if a hold violation is detected at a second transmitter circuit of the second die.

Once the global and local delay circuits have been tuned/adjusted, the configuration values for each delay can be stored in memory (e.g., an eFuse or other persistent memory) and applied to the configuration input of delay circuits following boot-up or reset, thereby fixing the delay following configuration. Similar control inputs can be stored and applied for each of the multiplexers at the first and second dies (e.g., the first multiplexers 340A and 340B, the second multiplexers 342A and 342B, the third multiplexers 346A and 346B). Using the aforementioned techniques, the first and second dies can be tuned to implement a hybrid system-synchronous and source-synchronous clock distribution scheme across any number of semiconductor dies.

In one aspect of the present disclosure, a semiconductor device is disclosed. The semiconductor device can include a first die having a transmission circuit and a first PLL circuit configured to generate a first global clock signal. The semiconductor device can include a second die having a receiver circuit, a phase aligned element, and a second PLL circuit. The phase aligned element is configured to generate a reference clock signal using the first global clock signal and feedback from the second PLL circuit. The second PLL circuit is configured to generate a second global clock signal based on the reference clock signal. The phases of the first global clock signal and the second global clock signal are aligned to facilitate data transfer from the transmission circuit to the receiver circuit.

In another aspect of the present disclosure, a semiconductor die is disclosed. The semiconductor die can include a PLL circuit configured to generate a first global clock signal. The semiconductor die can include a multiplexer configured to select between the first global clock signal and a second global clock signal forwarded from a second die electrically coupled to the semiconductor die. The semiconductor die can include a receiver circuit configured to receive an output from the multiplexer. The receiver circuit is configured to receive data transmitted by the second die.

In yet another aspect of the present disclosure, a method is disclosed. The method includes initiating a data transfer process in a system-synchronous mode between a first die and a second die having different clock domains. The method includes adjusting a first delay circuit of the first die such that a first latency corresponding to a first transmission circuit of the first die matches a second latency corresponding to a second transmission circuit of the second die. The method includes adjusting a second delay circuit of the first die according to a setup mismatch or a hold mismatch to generate a forwarded clock signal for the first die.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first die having a transmitter circuit and a first phase-locked loop (PLL) circuit configured to generate a first global clock signal; and
a second die having a receiver circuit, a phase aligned element, and a second PLL circuit, the phase aligned element configured to generate a reference clock signal using the first global clock signal and feedback from the second PLL circuit, the second PLL circuit configured to generate a second global clock signal based on the reference clock signal,
wherein phases of the first global clock signal and the second global clock signal are aligned to facilitate data transfer from the transmitter circuit to the receiver circuit.

2. The semiconductor device of claim 1, wherein the first die is electrically coupled to the second die using one or more of through-silicon vias (TSVs), wire bonding, micro-bumps, or through-die vias (TDVs).

3. The semiconductor device of claim 1, wherein the receiver circuit of the second die is configured to operate in a source-synchronous mode by receiving the first global clock signal forwarded from the first die via a die-to-die clock interface.

4. The semiconductor device of claim 1, wherein the receiver circuit of the second die is configured to operate in a system-synchronous mode by receiving the second global clock signal generated by the second PLL circuit.

5. The semiconductor device of claim 1, further comprising an on-chip clock correction circuit configured to correct a duty cycle of the first global clock signal.

6. The semiconductor device of claim 1, further comprising a programmable global delay circuit configured to:
receive the first global clock signal generated by the first PLL circuit; and
generate a first local clock signal having a delay selected according to a clock skew between the first global clock signal and the second global clock signal.

7. The semiconductor device of claim 1, wherein the first die further comprises a first receiver circuit configured to receive the second global clock signal forwarded from the second die in a source-synchronous configuration.

8. The semiconductor device of claim 1, wherein the first die further comprises a local delay circuit configured to delay one of an input clock for the transmitter circuit or an input clock for a first die-to-die clock transmission interface of the first die.

9. The semiconductor device of claim 8, wherein the second die further comprises a second local delay circuit configured to delay one of an input clock for a second transmitter circuit of the second die or an input clock for a second die-to-die clock transmission interface of the second die.

10. The semiconductor device of claim 1, wherein the first die further comprises a die-to-die global clock transmission interface configured to transmit the first global clock signal to the phase aligned element of the second die.

11. The semiconductor device of claim 1, further comprising:
a third die electrically coupled to the first die, the third die having a second receiver circuit, a second phase aligned element, and a third PLL circuit, the second phase aligned element configured to generate a second reference clock signal using the first global clock signal and feedback from the third PLL circuit, the third PLL circuit configured to generate a third global clock signal for the third die based on the second reference clock signal.

12. The semiconductor device of claim 11, wherein the first die further comprises a second transmitter circuit, and wherein phases of the first global clock signal and the third global clock signal are aligned to facilitate data transfer from the second transmitter circuit to the second receiver circuit.

13. A semiconductor die, comprising:
a phase-locked loop (PLL) circuit configured to generate a first global clock signal;
a multiplexer configured to select between the first global clock signal and a second global clock signal forwarded from a second die electrically coupled to the semiconductor die; and
a receiver circuit configured to receive an output from the multiplexer, the receiver circuit configured to receive data transmitted by the second die.

14. The semiconductor die of claim 13, further comprising a global delay circuit configured to apply a programmable delay to the first global clock signal, wherein the multiplexer is configured to select between the delayed first global clock signal and the second global clock signal.

15. The semiconductor die of claim 14, further comprising a local delay circuit configured to receive the delayed first global clock signal as input and generate a delayed local clock signal.

16. The semiconductor die of claim 15, further comprising:
a transmitter circuit configured to transmit data to the second die; and
a second multiplexer configured to select between the delayed first global clock signal and the delayed local clock signal, wherein an output of the second multiplexer is provided to the transmitter circuit.

17. The semiconductor die of claim 16, further comprising:
a die-to-die clock transmission interface configured to forward a clock signal to the second die; and
a third multiplexer configured to select between the delayed first global clock signal and the delayed local clock signal, wherein an output of the third multiplexer is provided to the die-to-die clock transmission interface.

18. A method, comprising:
initiating a data transfer process in a system-synchronous mode between a first die and a second die having different clock domains;
adjusting a first delay circuit of the first die such that a first latency corresponding to a first transmission circuit of the first die matches a second latency corresponding to a second transmission circuit of the second die; and
adjusting a second delay circuit of the first die according to a setup mismatch or a hold mismatch to generate a forwarded clock signal for the first die.

19. The method of claim 18, wherein initiating the data transfer process in the system-synchronous mode comprises causing a first multiplexer to output a first global clock signal of the first die to a first receiver circuit of the first die, wherein the first multiplexer is configured to select between the first global clock signal and a second global clock signal forwarded from the second die.

20. The method of claim 19, wherein adjusting the second delay circuit comprises switching to a source-synchronous mode by causing the first multiplexer to output the second global clock signal forwarded from the second die.
